(19) United States
(12) Patent Application Publication
(10) Pub. No.: US 2025/0015135 A1
(43) Pub. Date: Jan. 9, 2025

(54) VERTICAL CHANNEL TRANSISTORS HAVE ENHANCED SOURCE-TO-DRAIN CURRENT PATHS THEREIN

(71) Applicant: Samsung Electronics Co., Ltd., Suwon-si (KR)

(72) Inventors: Hwayeong Lee, Suwon-si (KR); Seulji Song, Suwon-si (KR)

(21) Appl. No.: 18/732,958

(22) Filed: Jun. 4, 2024

(30) Foreign Application Priority Data
Jul. 7, 2023 (KR) 10-2023-0088624

(51) Int. Cl. H01L 29/08; H01L 29/24; H01L 29/423; H01L 29/78; H10B 12/00

(52) U.S. Cl. CPC H01L 29/0847; H01L 29/24; H01L 29/42364; H01L 29/7827; H10B 12/482

(57) ABSTRACT

A vertical channel transistor includes a substrate having a bit line thereon, and a vertical channel layer including a first metal oxide, on the bit line. A lower insertion layer is provided, which extends between the bit line and a first end of the channel layer, and includes a second metal oxide having a greater bonding energy relative to the first metal oxide. A lower source/drain region is provided, which extends between the first end of the channel layer and the lower insertion layer, and includes a first metal dopant that is a reduced form of the first metal oxide. An upper source/drain region is provided, which is electrically connected to a second end of the channel layer, and includes the first metal dopant. An insulated gate line is provided on the channel layer.

### REFERENCE TO PRIORITY APPLICATION

This application claims priority under 35 U.S.C. § 119 to Korean Patent Application No. 10-2023-0088624, filed Jul. 7, 2023, the disclosure of which is hereby incorporated herein by reference.

### BACKGROUND

The inventive concept relates to semiconductor devices and, more particularly, to semiconductor devices having vertical transistors therein.

As the design rules of semiconductor devices are reduced, manufacturing technology is being developed to improve the integration of semiconductor devices and improve operation speed and yield thereof. To achieve these improvements, transistors with vertical channels have been proposed to expand the integration, the resistance, and the current driving ability of these semiconductor devices.

### SUMMARY

The inventive concept provides a semiconductor device with improved performance and reliability.

According to an aspect of the inventive concept, a semiconductor device is provided, which includes a substrate, a bit line extending in a first horizontal direction on the substrate, and a pair of gate lines extending on the bit line in a second horizontal direction intersecting with the first horizontal direction and spaced apart from each other in the first horizontal direction. A channel layer is also provided, which is disposed between the pair of gate lines, extends in a vertical direction, and includes a first metal oxide. A gate insulation layer is provided, which is disposed between each of the pair of gate lines and the channel layer; the gate insulation layer includes a vertical portion extending in the vertical direction. A lower insertion layer is provided, which is disposed between the bit line and the channel layer, extends in the first horizontal direction, and includes a second metal oxide, A lower source/drain region is provided, which is disposed between the channel layer and the lower insertion layer, and includes a first metal dopant that is a reduced form of the first metal oxide. An upper source/drain region is provided, which is spaced apart from the lower source/drain region (with the channel layer extending therebetween) and contains the first metal dopant. According to these aspects, the second metal oxide has greater bonding energy than the first metal oxide.

According to another aspect of the inventive concept, a semiconductor device is provided, which includes: a substrate, a bit line extending in a first horizontal direction on the substrate, a pair of gate lines extending on the bit line in a second horizontal direction intersecting with the first horizontal direction and spaced apart from each other in the first horizontal direction, a channel layer disposed between the pair of gate lines, extending in a vertical direction, and including a first metal oxide, a gate insulation layer disposed between each of the pair of gate lines and the channel layer and extending in the vertical direction, an upper insertion layer disposed on the channel layer and including a second metal oxide, and an upper source/drain region disposed between the channel layer and the upper insertion layer. The upper source/drain region includes a first metal dopant that is a reduced form of the first metal oxide. The second metal oxide may also have a greater bonding energy than the first metal oxide.

According to another aspect of the inventive concept, there is provided a semiconductor device. The semiconductor device includes a memory cell device, and a vertical transistor electrically connected to the memory cell device. The vertical transistor may include: a substrate, a bit line extending in a first horizontal direction on the substrate, a pair of gate lines extending on the bit line in a second horizontal direction intersecting with the first horizontal direction and spaced apart from each other in the first horizontal direction, a channel layer disposed between the pair of gate lines, extending in a vertical direction, and including a first metal oxide, a gate insulation layer disposed between each of the pair of gate lines and the channel layer and extending in the vertical direction, a lower insertion layer disposed between the bit line and the channel layer, extending in the first horizontal direction, and including a second metal oxide, a lower source/drain region disposed between the channel layer and the lower insertion layer, contacting the lower insertion layer, and including a first metal dopant that is a reduced form of the first metal oxide, an upper source/drain region spaced apart from the lower source/drain region with the channel layer therebetween and containing the first metal dopant, and an upper insertion layer disposed on the upper source/drain region, contacting the upper source/drain region, and including a third metal oxide. According to some of these embodiments, the second metal oxide has a greater bonding energy than the first metal oxide, and the third metal oxide has greater bonding energy than the first metal oxide.

According to a further aspect of the inventive concept, a vertical channel transistor is provided, which includes a substrate having a bit line thereon, and a channel layer comprising a first metal oxide, on the bit line. A lower insertion layer is also provided, which extends between the bit line and a first end of the channel layer; the lower insertion layer includes a second metal oxide having a greater bonding energy relative to the first metal oxide. A lower source/drain region is provided, which extends between the first end of the channel layer and the lower insertion layer, and includes a first metal dopant that is a reduced form of the first metal oxide. An upper source/drain region is also provided, which is electrically connected to a second end of the channel layer, and includes the first metal dopant. An insulated gate line is provided on the channel layer. Advantageously, the channel layer extends lengthwise in a vertical direction relative to a surface of the substrate, and the first metal oxide comprises at least one InₓGa_{y}Zn_{z}O material, where: 0≤x<1, 0≤y<1, and 0≤z<1.

### BRIEF DESCRIPTION OF THE DRAWINGS

Embodiments of the inventive concept will be more clearly understood from the following detailed description taken in conjunction with the accompanying drawings in which:

FIG. 1 is a layout view of a semiconductor device according to embodiments;

FIG. 2 is a cross-sectional view taken along a line X-X of FIG. 1;

FIGS. 3A and 3B are enlarged cross-sectional views of a region EX1 and a region EX2 of FIG. 2, respectively;

FIGS. 4A to 4C are cross-sectional views of semiconductor devices according to embodiments;

FIGS. 5 to 7 are cross-sectional views of semiconductor devices according to embodiments;

FIGS. 8, 9A to 9C, 10A to 10C, and 11 to 13 are cross-sectional views showing a method of manufacturing a semiconductor device, according to embodiments; and

FIG. 14 is a cross-sectional view of a semiconductor device according to embodiments.

### DETAILED DESCRIPTION OF THE EMBODIMENTS

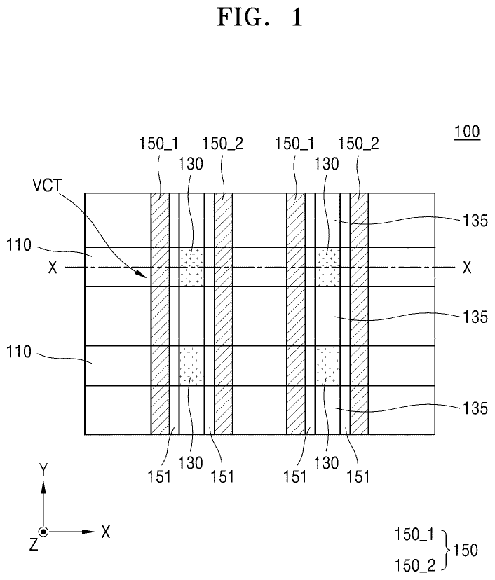

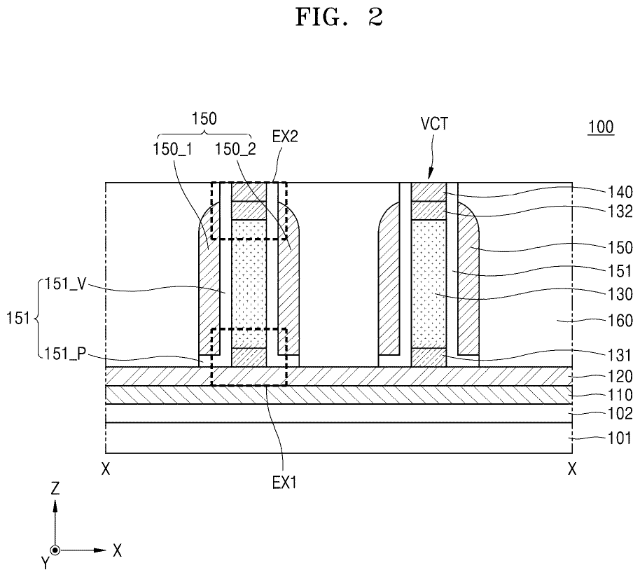

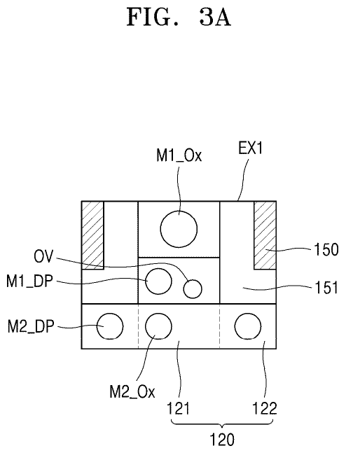

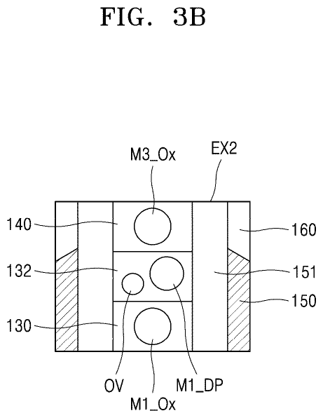

FIG. 1 is a layout view of a semiconductor device 100 according to embodiments; FIG. 2 is a cross-sectional view taken along a line X-X of FIG. 1; and FIGS. 3A and 3B are enlarged cross-sectional views of a region EX1 and a region EX2 of FIG. 2, respectively. Referring to FIGS. 1 and 2, the semiconductor device 100 may include a plurality of vertical transistors VCT arranged on a substrate 101.

As shown in FIG. 2, a lower insulation layer 102 may be disposed on the substrate 101. The substrate 101 may include silicon, e.g., monocrystalline silicon, polycrystalline silicon, or amorphous silicon. In some other embodiments, the substrate 101 may include at least one selected from among Ge, SiGe, SiC, GaAs, InAs, and InP. According to some embodiments, the substrate 101 may include a conductive region, e.g., a well doped with an impurity or a structure doped with an impurity. The lower insulation layer 102 may include an oxide film, a nitride film, or a combination thereof.

According to some embodiments, a bit line 110 extending in a first horizontal direction (X direction) may be disposed on the lower insulation layer 102. According to some embodiments, the bit line 110 may include Ti, TIN, Ta, TaN, Mo, Ru, W, WN, Co, Ni, TiSi, TiSiN, WSi, WSiN, TaSi, TaSiN, RuTiN, CoSi, NiSi, polysilicon, or a combination thereof. For example, the bit line 110 may include a conductive layer (not shown) and a conductive barrier (not shown) disposed on the top surface and the bottom surface of the conductive layer. A bit line insulation layer (not shown) extending in the first horizontal direction (X direction) may be disposed on a sidewall of the bit line 110. For example, the bit line insulation layer may fill the space between two adjacent bit lines BL and have the same height as the bit lines 110.

According to some embodiments, a pair of gate lines 150 extending in a second horizontal direction (Y direction) that intersects with the first horizontal direction (X direction) may be arranged on the bit line 110. According to some embodiments, the pair of gate lines 150 may include a first gate line 150_1 and a second gate line 150_2 spaced apart from each other in the first horizontal direction (X direction). According to some embodiments, the gate lines 150 may include Ti, TIN, Ta, TaN, Mo, Ru, W, WN, TiSiN, WSiN, polysilicon, or a combination thereof.

According to some embodiments, a channel layer 130 extending in a vertical direction (Z direction) and surrounded by a mold insulation layer 135 may be disposed between the pair of gate lines 150.

According to some embodiments, the channel layer 130 may include an oxide semiconductor material. In detail, the channel layer 130 may include a first metal oxide M1_Ox (refer to FIGS. 3A and 3B). For example, the first metal oxide M1_Ox may include at least one of zinc tin oxide (ZnₓSn_{y}O), indium oxide (InₓO), zinc oxide (ZnOₓ), indium zinc oxide (InₓZn_{y}O), indium gallium zinc oxide (InₓGa_{y}Zn_{z}O), indium gallium silicon oxide (InₓGa_{y}Si_{z}O), indium tungsten oxide (InₓW_{y}O), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}SnO), gallium zinc tin oxide (GaₓZn_{y}Sn_{z}O), and zirconium zinc tin oxide (ZrₓZn_{y}Sn_{z}O). Here, x, y, and z may be equal to or greater than 0 and less than 1.

According to other embodiments, the channel layer 130 may include a 2-dimensional semiconductor material, wherein the 2-dimensional semiconductor material may include graphene, carbon nanotubes, or a combination thereof. According to other embodiments, the channel layer 130 may include Ti, TiN, Ta, TaN, W, WN, TiSiN, WSiN, polysilicon, or a combination thereof.

According to some embodiments, a pair of gate insulation layers 151 extending in the second horizontal direction (Y direction) may be arranged between each of the pair of gate lines 150 and the channel layer 130. In detail, a gate insulation layer 151 may be disposed between the first gate line 150_1 and the channel layer 130. In detail, the gate insulation layer 151 may be disposed between the second gate line 150_2 and the channel layer 130.

According to some embodiments, the gate insulation layer 151 may include a vertical extension 151_V extending in the vertical direction (Z direction) between the gate lines 150 and the channel layer 130 and a horizontal extension 151_P extending in the first horizontal direction (X direction) between the gate lines 150 and the bit line 110. For example, the gate insulation layer 151 may have an L-shaped cross-section, as shown by FIG. 2. According to some embodiments, the gate lines 150 may be spaced apart from a lower insertion layer 120 with the horizontal extension 151_P of the gate insulation layer 151 therebetween.

According to some embodiments, a gate insulation layer 151 may include at least one selected from a group consisting of a high-k dielectric material and a ferroelectric material having a dielectric constant higher than that of silicon oxide. For example, the gate insulation layer 151 may include at least one material selected from the group consisting of among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

According to some embodiments, the lower insertion layer 120 extending in the first horizontal direction (X direction) may be disposed on the bit line 110. In detail, the lower insertion layer 120 may be disposed between the bit line 110 and the channel layer 130. And, according to some embodiments, the lower insertion layer 120 may include a second metal oxide M2_Ox (refer to FIG. 3A). For example, the second metal oxide M2_Ox may be selected from among materials having bonding energy greater than the bonding energy of the first metal oxide M1_Ox of the channel layer 130.

For example, when the first metal oxide M1_Ox of the channel layer 130 is indium gallium zinc oxide (InₓGa_{y}Zn_{z}O) (where x, y, and z are equal to or greater than 0 and less than 1), the second metal oxide M2_Ox of the lower insertion layer 120 may be selected from among materials having bonding energy greater than that of indium gallium zinc oxide (InₓGa_{y}Zn_{z}O). For example, the second metal oxide M2_Ox may be selected from among aluminum oxide (AlₓO), tungsten oxide (WₓO), titanium oxide (TiₓO), tantalum oxide (TaₓO), molybdenum oxide (MoₓO), ruthenium oxide (RuₓO), cobalt oxide (CoₓO), germanium oxide (GeₓO), indium tin oxide (InₓSn_{y}O), and tin oxide (SnₓO). According to some embodiments, the second metal oxide M2_Ox may include a conductive oxide. According to some embodiments, the second metal oxide M2_Ox may include a metal oxide with high mobility. The lower insertion layer 120 and the second metal oxide M2_Ox will be described in detail with reference to FIG. 3A.

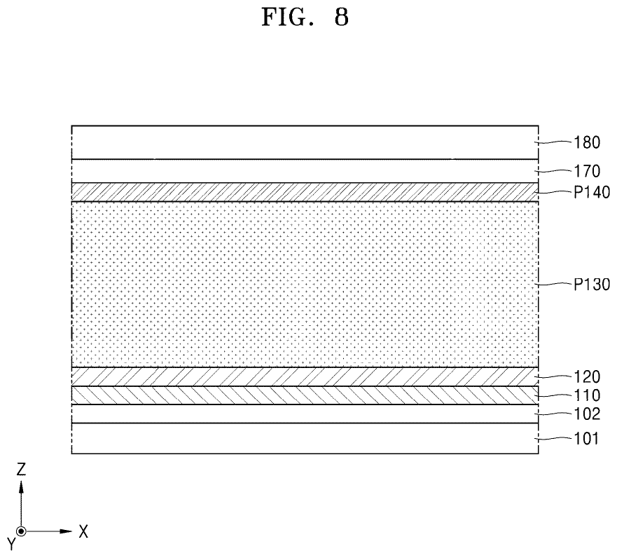

According to some embodiments, the lower insertion layer 120 may be disposed under the channel layer 130 to form a lower source/drain region 131. The process of forming the lower source/drain region 131 by using the lower insertion layer 120 will be described in detail with reference to FIGS. 8A to 8G.

According to some further embodiments, an upper insertion layer 140 may be disposed on the channel layer 130, as shown by FIG. 2. This upper insertion layer 140 may include a third metal oxide M3_Ox (refer to FIG. 3B). According to some embodiments, the third metal oxide M3_Ox may be selected from among materials having bonding energy greater than the bonding energy of the first metal oxide M1_Ox of the channel layer 130.

For example, when the first metal oxide M1_Ox of the channel layer 130 is indium gallium zinc oxide (InₓGa_{y}Zn_{z}O) (where x, y, and z are equal to or greater than 0 and less than 1), the third metal oxide M3_Ox of the upper insertion layer 140 may be selected from among materials having bonding energy greater than that of indium gallium zinc oxide (InₓGa_{y}Zn_{z}O). For example, the third metal oxide M3_Ox may be selected from among aluminum oxide (AlₓO), tungsten oxide (WₓO), titanium oxide (TiₓO), tantalum oxide (TaₓO), molybdenum oxide (MoₓO), ruthenium oxide (RuₓO), cobalt oxide (CoₓO), germanium oxide (GeₓO), indium tin oxide (InₓSn_{y}O), and tin oxide (SnₓO). According to some embodiments, the third metal oxide M3_Ox may include a conductive oxide. According to some embodiments, the third metal oxide M3_Ox may include a metal oxide with high mobility. The upper insertion layer 140 and the third metal oxide M3_Ox will be described in detail with reference to FIG. 3B.

According to some embodiments, the upper insertion layer 140 may be disposed on the channel layer 130 to form an upper source/drain region 132. The process of forming the upper source/drain region 132 by using the upper insertion layer 140 will be described in detail with reference to FIGS. 8A to 8G.

According to some embodiments, the lower source/drain region 131 may be disposed between the channel layer 130 and the lower insertion layer 120. The lower source/drain region 131 may be disposed on the lower insertion layer 120 and in contact with the lower insertion layer 120. According to some embodiments, the lower source/drain region 131 may include a first metal dopant M1_DP and an oxygen vacancy OV. In detail, the lower source/drain region 131 may include the first metal dopant M1_DP, which is a reduced form of the first metal oxide M1_Ox of the channel layer 130. The lower source/drain region 131 will be described in detail with reference to FIG. 3A.

According to some embodiments, the upper source/drain region 132 may be disposed between the channel layer 130 and the upper insertion layer 140. The upper source/drain region 132 may be disposed under and in contact with the upper insertion layer 140. According to some embodiments, the upper source/drain region 132 may be disposed between the pair of gate lines 150. For example, the upper source/drain region 132 may overlap the pair of gate lines 150 in the first horizontal direction (X direction). According to some embodiments, the upper source/drain region 132 may include the first metal dopant M1_DP and the oxygen vacancy OV. The upper source/drain region 132 will be described in detail with reference to FIG. 3B.

According to some embodiments, an interlayer insulation layer 160 may be disposed to surround a vertical transistor VCT in a horizontal direction. For example, the interlayer insulation layer 160 may surround the vertical transistor VCT in the first horizontal direction (X direction). In detail, the interlayer insulation layer 160 may surround the channel layer 130 on the bit line 110 in the first horizontal direction (X direction). In detail, the interlayer insulation layer 160 may surround the channel layer 130 on the lower insertion layer 120 in the first horizontal direction (X direction). In detail, the interlayer insulation layer 160 may surround the lower source/drain region 131 and the upper source/drain region 132 in the first horizontal direction (X direction). In detail, the interlayer insulation layer 160 may surround the pair of gate lines 150 in the first horizontal direction (X direction). The interlayer insulation layer 160 may surround the upper insertion layer 140 in the first horizontal direction (X direction).

Referring to FIG. 3A, the lower insertion layer 120 may include a first region 121 that overlaps the lower source/drain region 131 in the vertical direction (Z direction). In other words, the first region 121 may overlap the channel layer 130 in the vertical direction (Z direction). The first region 121 may include a region that does not overlap the channel layer 130 in the vertical direction (Z direction). The first region 121 may include the second metal oxide M2_Ox. As described above, the second metal oxide M2_Ox may be selected from among materials having bonding energy greater than the bonding energy of the first metal oxide M1_Ox of the channel layer 130.

According to some embodiments, the lower insertion layer 120 may include a second region 122 that does not overlap the lower source/drain region 131 in the vertical direction (Z direction). In other words, the second region 122 may not overlap the channel layer 130 in the vertical direction (Z direction). In detail, the second region 122 may overlap the gate insulation layer 151 in the vertical direction (Z direction). The second region 122 may include the second metal dopant M2_DP. In detail, the second region 122 may include a second metal dopant M2_DP, which is a reduced form of the second metal oxide M2_Ox.

According to some embodiments, as shown in FIG. 3A, the channel layer 130 may include the first metal oxide M1_Ox, and the lower source/drain region 131 disposed between the channel layer 130 and the lower insertion layer 120 may include the first metal dopant M1_DP, which is a reduced form of the first metal oxide M1_Ox. Furthermore, the lower source/drain region 131 may include the oxygen vacancy OV generated as the first metal oxide M1_Ox is reduced. In other words, the lower source/drain region 131 may include the first metal dopant M1_DP and the oxygen vacancy OV generated as the first metal oxide M1_Ox is reduced. The lower source/drain region 131 may exhibit electrical conductivity due to the first metal dopant M1_DP and the oxygen vacancy OV.

Referring to FIG. 3B, as described above, the upper insertion layer 140 may include the third metal oxide M3_Ox having bonding energy greater than the bonding energy of the first metal oxide M1_Ox of the channel layer 130.

According to some embodiments, as shown in FIG. 3B, the channel layer 130 may include the first metal oxide M1_Ox, and the upper source/drain region 132 disposed between the channel layer 130 and the upper insertion layer 140 may include the first metal dopant M1_DP, which is a reduced form of the first metal oxide M1_Ox. Furthermore, the upper source/drain region 132 may include the oxygen vacancy OV generated as the first metal oxide M1_Ox is reduced. In other words, the upper source/drain region 132 may include the first metal dopant M1_DP and the oxygen vacancy OV generated as the first metal oxide M1_Ox is reduced. The upper source/drain region 132 may exhibit electrical conductivity due to the first metal dopant M1_DP and the oxygen vacancy OV.

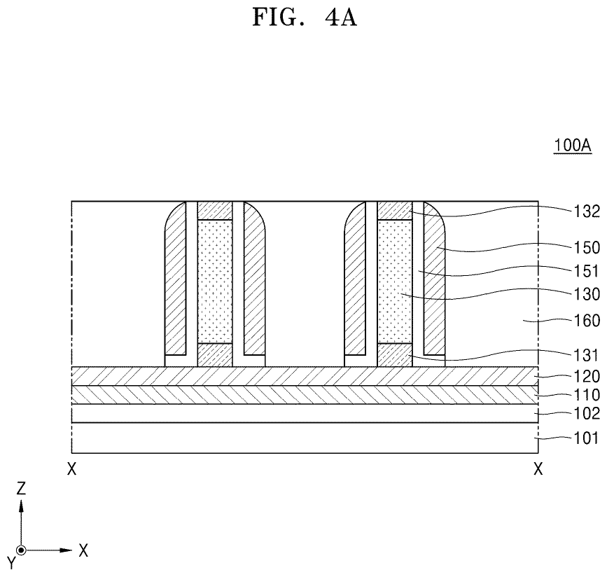

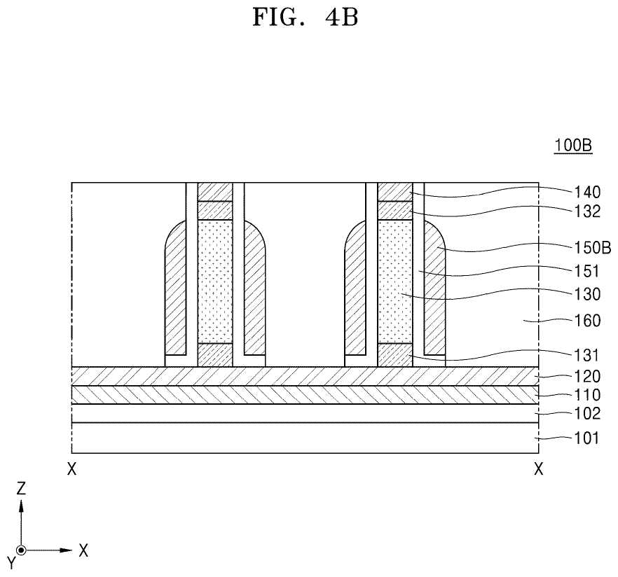

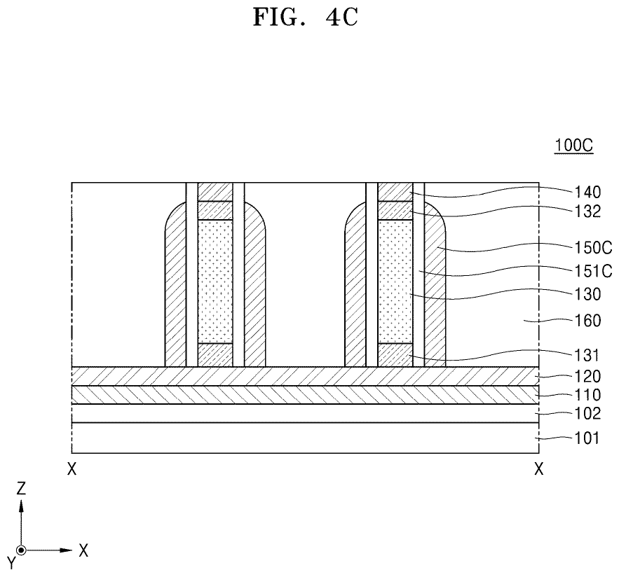

FIGS. 4A to 4C are cross-sectional views of semiconductor devices 100A, 100B, and 100C according to embodiments, respectively. Descriptions below focus on the differences from the semiconductor device 100 described with reference to FIGS. 1, 2, 3A, and 3B.

Referring to FIG. 4A, a semiconductor device 100A may not include the upper insertion layer 140 (refer to FIG. 2). In other words, unlike the semiconductor device 100 (refer to FIG. 2) that includes the upper insertion layer 140 disposed on the upper source/drain region 132, the upper insertion layer 140 may not be disposed on the upper source/drain region 132 in the semiconductor device 100A.

According to some embodiments, the semiconductor device 100A may be fabricated by forming the upper source/drain region 132 by using the upper insertion layer 140 and then removing the upper insertion layer 140. According to some other embodiments, the semiconductor device 100A may be fabricated by forming the upper source/drain region 132 by performing a separate doping process without using the upper insertion layer 140.

Referring to FIG. 4B, a semiconductor device 100B may include a pair of gate lines 150B arranged on the sidewall of the channel layer 130. The pair of gate lines 150B may not overlap the upper source/drain region 132 in the first horizontal direction (X direction).

Referring to FIG. 4C, a semiconductor device 100C includes a pair of gate lines 150C and a pair of gate insulation layers 151C arranged between each of the pair of gate lines 150C and the channel layer 130. In detail, the pair of gate lines 150C may extend in the second horizontal direction (Y direction) on the bit line 110. Likewise, the pair of gate insulation layers 151C may extend in the second horizontal direction (Y direction) on the bit line 110. Unlike the gate insulation layer 151 of the semiconductor device 100 having an L-shaped cross-section, the gate insulation layers 151C of the semiconductor device 100C may have an I-shaped cross-section.

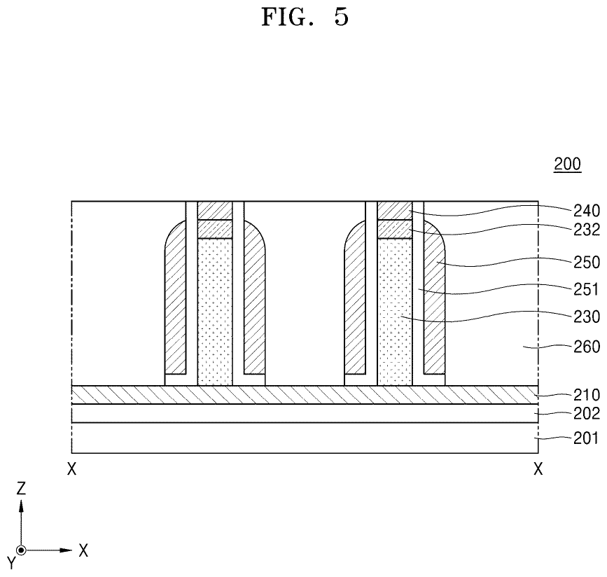

FIGS. 5 to 7 are cross-sectional views of semiconductor devices 200, 200A, and 201 according to alternative embodiments, respectively. Referring to FIG. 5, the semiconductor device 200 may not include the lower insertion layer 120 (refer to FIG. 2) and the lower source/drain region 131 (refer to FIG. 2). In other words, unlike the semiconductor device 100 (refer to FIG. 2) in which the lower insertion layer 120 and the lower source/drain region 131 are arranged between the bit line 110 and the channel layer 130, in the semiconductor device 200, the lower insertion layer 120 and the lower source/drain region 131 may not be arranged between the bit line 210 and a channel layer 230.

According to some embodiments, in the process of manufacturing the semiconductor device 200, an upper source/drain region 232 may be formed using an upper insertion layer 240. On the other hand, the lower source/drain region 131 may not be formed, and thus, the lower insertion layer 120 used to form the same may not be formed either.

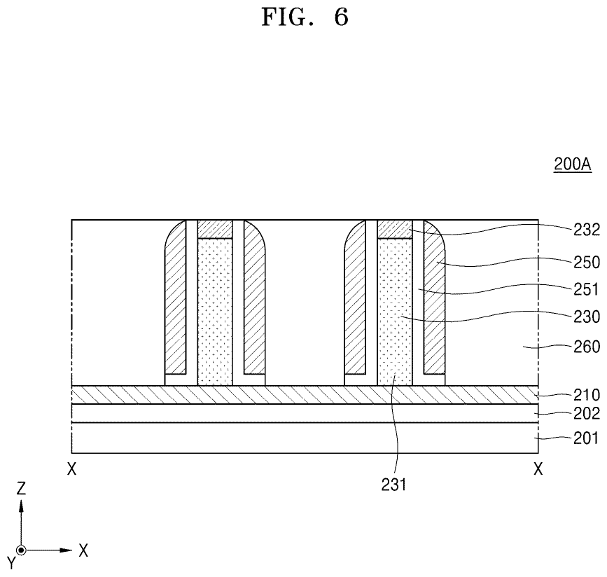

Referring to FIG. 6, the semiconductor device 200A may not include the lower insertion layer 120 (refer to FIG. 2), the lower source/drain region 131 (refer to FIG. 2), and the upper insertion layer 140 (refer to FIG. 2). In other words, unlike the semiconductor device 100 (refer to FIG. 2) in which the lower insertion layer 120 and the lower source/drain region 131 are arranged between the bit line 110 and the channel layer 130 and the upper insertion layer 140 is disposed on the upper source/drain region 132, in the semiconductor device 200A, the lower insertion layer 120 and the lower source/drain region 131 are not arranged between a bit line 210 and the channel layer 230 and the upper insertion layer 140 may not be disposed on the upper source/drain region 132.

According to some embodiments, in the process of manufacturing the semiconductor device 200, an upper source/drain region 232 is formed using the upper insertion layer 140 but may be removed later. On the other hand, the lower source/drain region 131 may not be formed, and thus, the lower insertion layer 120 used to form the same may not be formed either.

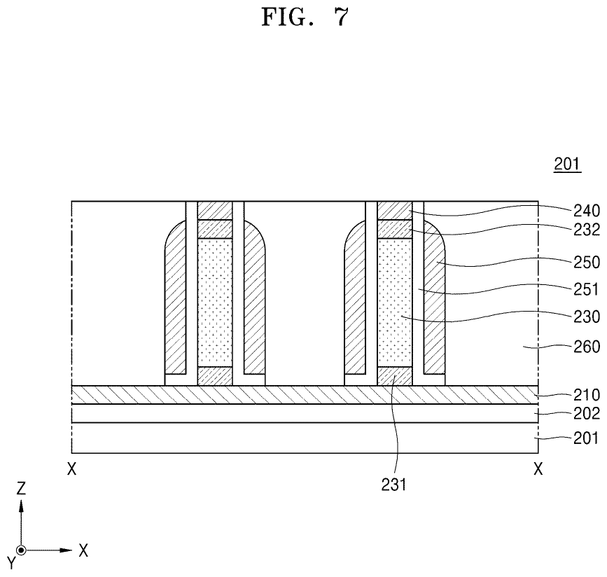

Referring to FIG. 7, a semiconductor device 201 may not include the lower insertion layer 120 (refer to FIG. 2). In other words, unlike the semiconductor device 100 (refer to FIG. 2) in which the lower insertion layer 120 and the lower source/drain region 131 are arranged between the bit line 110 and the channel layer 130, the semiconductor device 201 includes a lower source/drain region 231, but may not include the lower insertion layer 120 for forming the lower source/drain region 231.

According to some embodiments, unlike the semiconductor device 100 in which the lower source/drain region 231 is formed by using the lower insertion layer 120, the lower insertion layer 120 may not be used to form the lower source/drain region 231 of the semiconductor device 201. According to some embodiments, a separate doping process may be performed to form the lower source/drain region 231.

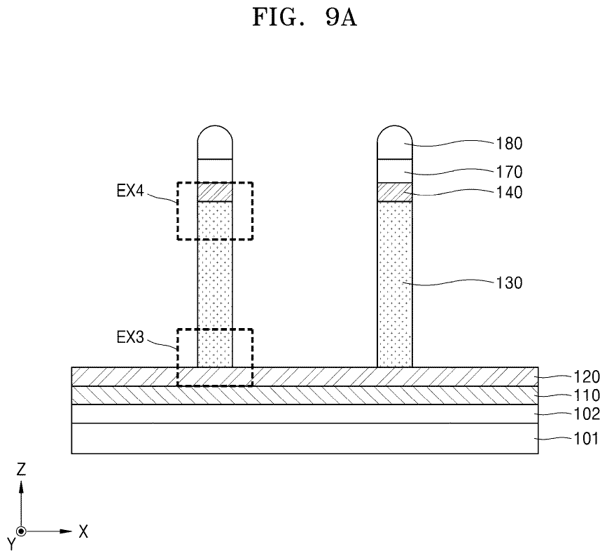

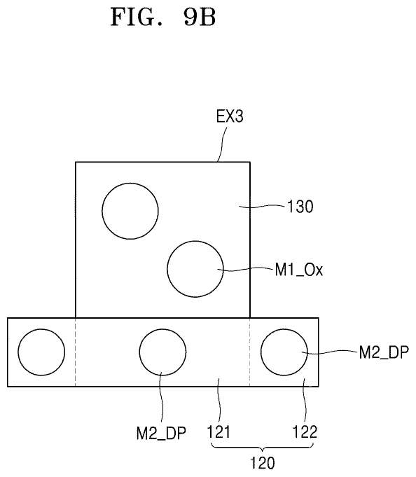

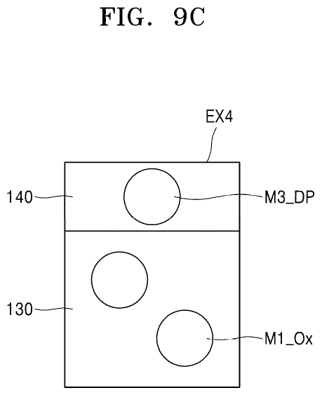

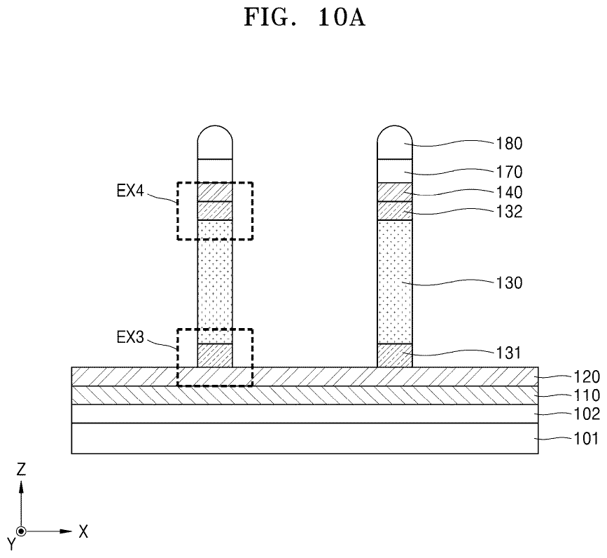

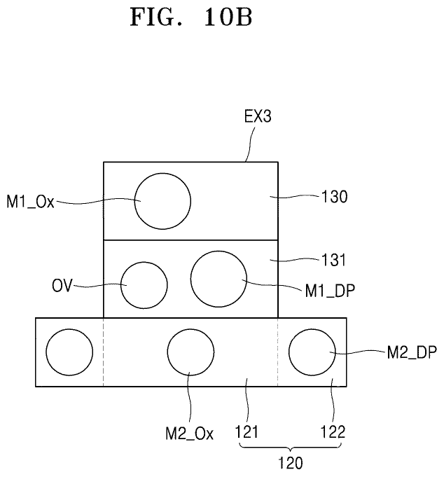

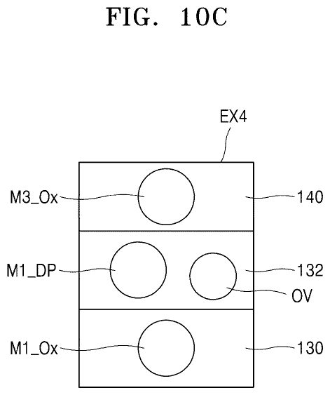

FIGS. 8, 9A to 90, 10A to 10C, and 11 to 13 are cross-sectional views showing a method of manufacturing a semiconductor device, according to embodiments. In detail, FIGS. 8, 9A, 10A, and 11 to 13 are cross-sectional views corresponding to a line X-X of FIG. 1. FIGS. 9B and 9C are enlarged cross-sectional views of a region EX3 and a region EX4 of FIG. 9A, respectively. FIGS. 10B and 10C are enlarged cross-sectional views of a region EX3 and a region EX4 of FIG. 10A, respectively.

Referring to FIG. 8, the lower insulation layer 102 and the bit line 110 may be sequentially arranged on the substrate 101. The lower insertion layer 120 may be disposed on the bit line 110. Subsequently, a pre-channel layer P130 and a pre-upper insertion layer P140 may be arranged on the lower insertion layer 120. The pre-channel layer P130 may extend in the first horizontal direction (X direction) and may be surrounded by the mold insulation layer 135 (refer to FIG. 1) in the second horizontal direction (Y direction). An etch stop layer 170 and a mask layer 180 may be arranged on the pre-upper insertion layer P140. The mask layer 180 may be used to etch the pre-channel layer P130 in a subsequent process.

Referring to FIG. 9A, the channel layer 130 and the upper insertion layer 140 may be formed by patterning the pre-channel layer P130 and the pre-upper insertion layer P140. To form the channel layer 130 and the upper insertion layer 140, the mask layer 180 may be used. In the process of forming the channel layer 130 and the upper insertion layer 140, portions of the etch stop layer 170 and the mask layer 180 may also be etched. According to some other embodiments, the mask layer 180 may be removed after the channel layer 130 and the upper insertion layer 140 are formed.

Referring to FIG. 9B, the channel layer 130 may include the first metal oxide M1_Ox. The lower insertion layer 120 may include the first region 121 that overlaps the channel layer 130 in the vertical direction (Z direction) and the second region 122 that does not overlap the channel layer 130 in the vertical direction (Z direction). The lower insertion layer 120 may include the second metal dopant M2_DP. In detail, the first region 121 and the second region 122 of the lower insertion layer 120 may include the second metal dopant M2_DP. Referring to FIG. 9C, and as described above, the channel layer 130 may include the first metal oxide M1_Ox. The upper insertion layer 140 may include a third metal dopant M3_DP.

Referring to FIG. 10A, an annealing process may be performed to form the lower source/drain region 131 and the upper source/drain region 132. In detail, a portion of the channel layer 130 in contact with the lower insertion layer 120 may be reduced through the annealing process. As a result, the lower source/drain region 131 in contact with the lower insertion layer 120 may be formed. In detail, a portion of the channel layer 130 in contact with the upper insertion layer 140 may be reduced through the annealing process. As a result, the upper source/drain region 132 in contact with the upper insertion layer 140 may be formed.

In detail, referring to FIG. 10B, a portion of the channel layer 130 in contact with the lower insertion layer 120 may be reduced. In other words, the first metal oxide M1_Ox present in a portion of the channel layer 130 may lose oxygen atoms. As a result, a portion of the lower insertion layer 120 may be oxidized. In other words, the second metal dopant M2_DP present in a portion of the lower insertion layer 120 may obtain oxygen atoms. For example, the first region 121 of the lower insertion layer 120 in contact with the channel layer 130 may be oxidized, and the second metal dopant M2_DP present in the first region 121 may obtain oxygen atoms. As a result, the second metal oxide M2_Ox may be formed.

As described above, the second metal oxide M2_Ox may be selected from among materials having bonding energy greater than that of the first metal oxide M1_Ox, and thus, the second metal oxide M2_Ox is more stable than the first metal oxide M1_Ox. Therefore, the first metal oxide M1_Ox may be reduced through the annealing process, and the second metal oxide M2_Ox may be formed.

Through the above-stated process, the first region 121 of the lower insertion layer 120 may be oxidized by obtaining oxygen atoms, and a portion of the channel layer 130 in contact with the first region 121 may be reduced by losing oxygen atoms. The reduced portion of the channel layer 130 may become the lower source/drain region 131. The lower source/drain region 131 may be disposed between the channel layer 130 and the lower insertion layer 120.

According to some embodiments, the lower source/drain region 131 may include the first metal dopant M1_DP and the oxygen vacancy OV formed as the first metal oxide M1_Ox is reduced. As the first metal oxide M1_Ox loses oxygen to the second metal dopant M2_DP in the first region 121 of the lower insertion layer 120, the oxygen vacancy OV may be formed. An unreduced portion of the channel layer 130 may still include the first metal oxide M1_Ox.

According to some embodiments, the first region 121 of the lower insertion layer 120 may include the second metal oxide M2_Ox formed as the second metal dopant M2_DP is oxidized. The second region 122 of the lower insertion layer 120 may still include the second metal dopant M2_DP.

In detail, referring to FIG. 10C, a portion of the channel layer 130 in contact with the upper insertion layer 140 may be reduced. In other words, the first metal oxide M1_Ox present in a portion of the channel layer 130 may lose oxygen atoms. As a result, the upper insertion layer 140 may be oxidized. In other words, the third metal dopant M3_DP present in the upper insertion layer 140 may obtain oxygen atoms. For example, the upper insertion layer 140 in contact with the channel layer 130 may be oxidized, and the third metal dopant M3_DP present in the upper insertion layer 140 may obtain oxygen atoms. As a result, the third metal oxide M3_Ox may be formed.

As described above, the third metal oxide M3_Ox may be selected from among materials having bonding energy greater than that of the first metal oxide M1_Ox, and thus, the third metal oxide M3_Ox is more stable than the first metal oxide M1_Ox. Therefore, the first metal oxide M1_Ox may be reduced through the annealing process, and the third metal oxide M3_Ox may be formed.

Through the above-stated process, the upper insertion layer 140 may be oxidized by obtaining oxygen atoms, and a portion of the channel layer 130 in contact with the upper insertion layer 140 may be reduced by losing oxygen atoms (i.e., creating oxygen vacancies). The reduced portion of the channel layer 130 may become the upper source/drain region 132. The upper source/drain region 132 may be disposed between the channel layer 130 and the upper insertion layer 140.

According to some embodiments, the upper source/drain region 132 may include the first metal dopant M1_DP and the oxygen vacancy OV formed as the first metal oxide M1_Ox is reduced. As the first metal oxide M1_Ox loses oxygen to the third metal dopant M3_DP in the upper insertion layer 140, the oxygen vacancy OV may be formed. An unreduced portion of the channel layer 130 may still include the first metal oxide M1_Ox.

According to some embodiments, the upper insertion layer 140 may include the third metal oxide M3_Ox formed as the third metal dopant M3_DP is oxidized. According to some other embodiments, only the third metal dopant M3_DP in a portion of the upper insertion layer 140 may be oxidized, and the remaining portion of the upper insertion layer 140 that is not oxidized may still include the third metal dopant M3_DP.

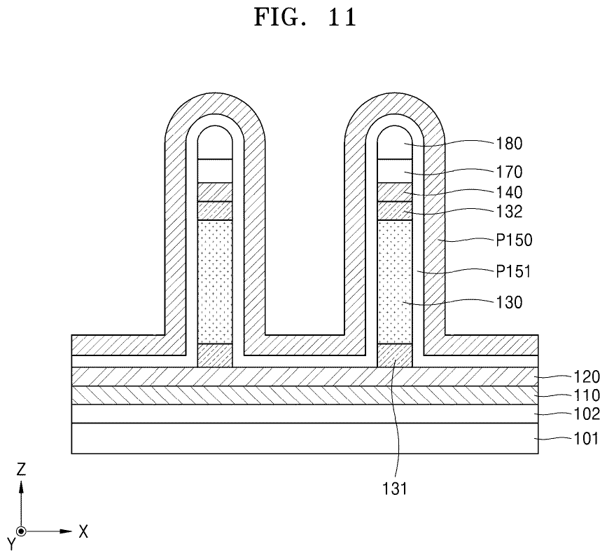

Referring to FIG. 11, a pre-gate insulation layer P151 and a pre-gate line P150 conformally covering the lower insertion layer 120, the lower source/drain region 131, the channel layer 130, the upper source/drain region 132, the upper insertion layer 140, the etch stop layer 170, and the mask layer 180 may be formed. In detail, the pre-gate insulation layer P151 and the pre-gate line P150 may be conformally formed on the top surface of the lower insertion layer 120, exposed side surfaces of the lower source/drain region 131, the channel layer 130, the upper source/drain region 132, the upper insertion layer 140, and the etch stop layer 170, and the top surface and side surfaces of the mask layer 180.

According to some other embodiments, when the mask layer 180 is already removed, the pre-gate insulation layer P151 and the pre-gate line P150 may conformally cover the lower insertion layer 120, the lower source/drain region 131, the channel layer 130, the upper source/drain region 132, the upper insertion layer 140, and the etch stop layer 170.

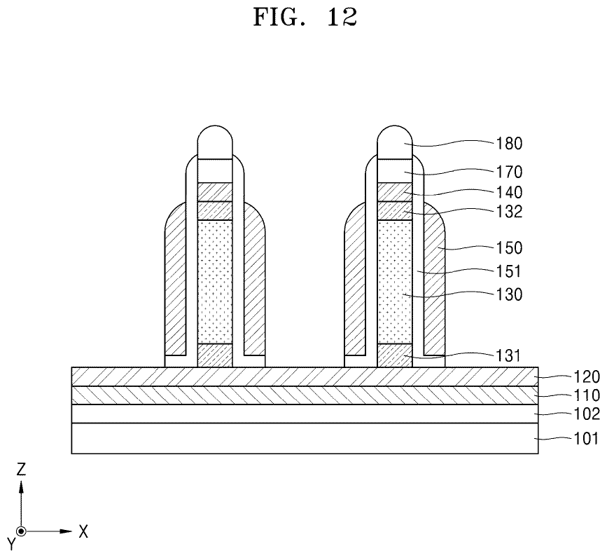

Referring to FIG. 12, the gate insulation layer 151 and the gate line 150 may be formed by etching the pre-gate insulation layer P151 and the pre-gate line P150. In detail, the pre-gate insulation layer P151 and the pre-gate line P150 may be etched to expose a portion of the lower insertion layer 120 and the top surface and side surfaces of the mask layer 180. According to some other embodiments, when the mask layer 180 is already removed, the gate insulation layer 151 and the gate line 150 may expose the top surface and the side surfaces or the top surface of the etch stop layer 170. According to some other embodiments, the gate insulation layer 151 may not expose a portion of the lower insertion layer 120.

According to some embodiments, the gate insulation layer 151 may overlap the lower source/drain region 131, the channel layer 130, the upper source/drain region 132, the upper insertion layer 140, and the etch stop layer 170 in the first horizontal direction (X direction). According to some embodiments, a gate line 150 is formed on the gate insulation layer 151 and may overlap the lower source/drain region 131, the channel layer 130, and the upper source/drain region 132 in the first horizontal direction (X direction). According to some other embodiments, the gate line 150 may not overlap the upper source/drain region 132 in the first horizontal direction (X direction) (refer to FIG. 4B).

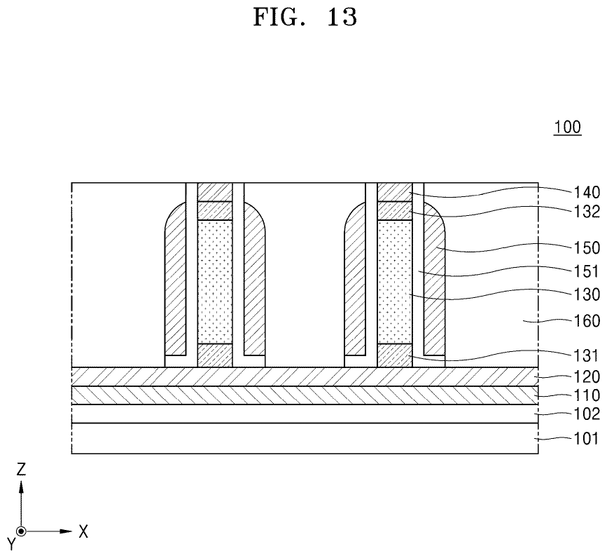

Referring to FIG. 13, the mask layer 180, the etch stop layer 170, and a portion of the gate insulation layer 151 surrounding the mask layer 180 and the etch stop layer 170 may be removed through a chemical mechanical polishing (CMP) process. During the CMP process, the upper insertion layer 140 and the upper source/drain region 132 may not be removed by using the etch stop layer 170, but the mask layer 180, the etch stop layer 170, and the portion of the gate insulation layer 151 surrounding the mask layer 180 and the etch stop layer 170 may be removed. According to some other embodiments, the upper insertion layer 140 may also be removed. The upper insertion layer 140 may be removed by continuing the CMP process for a certain period of time after the etch stop layer 170 is removed.

Subsequently, the semiconductor device 100 may be manufactured by forming the interlayer insulation layer 160 surrounding the lower source/drain region 131, the channel layer 130, the upper source/drain region 132, the upper insertion layer 140, the gate insulation layer 151, and the gate line 150 in the first horizontal direction (X direction) on the lower insertion layer 120.

According to some other embodiments, the semiconductor device 100 may be manufactured by using a method different from the method of manufacturing a semiconductor device described with reference to FIGS. 8 to 13.

According to an embodiment, the annealing process described with reference to FIGS. 10A to 10C may be performed before the patterning process for forming the channel layer 130 is performed. In other words, as described with reference to FIG. 8, the annealing process may be performed after the lower insulation layer 102, the bit line 110, the pre-channel layer P130, the pre-upper insertion layer P140, the etch stop layer 170, and the mask layer 180 are sequentially formed on the substrate 101.

As a result, a portion of the pre-channel layer P130 in contact with the lower insertion layer 120 may be reduced, and the lower insertion layer 120 may be oxidized. The reduced portion of the pre-channel layer P130 may form a lower source/drain region. Likewise, a portion of the pre-channel layer P130 in contact with the upper insertion layer 140 may be reduced, and the upper insertion layer 140 may be oxidized. The reduced portion of the pre-channel layer P130 may form an upper source/drain region. Subsequently, the semiconductor device 100 may be manufactured by performing a subsequent process such as a patterning process to form the channel layer 130.

According to another embodiment, the annealing process may be performed after the pre-gate insulation layer P151 and the pre-gate line P150 are formed. According to another embodiment, the annealing process may be performed after the pre-gate insulation layer P151 and the pre-gate line P150 are formed and before the patterning process for forming the gate insulation layer 151 and the gate line 150 is performed. According to another embodiment, the annealing process may be performed after the patterning process for forming the gate insulation layer 151 and the gate line 150 is performed. As a result, the semiconductor device 100 may be manufactured.

According to embodiments, the semiconductor device 100 including the lower insertion layer 120 and/or the upper insertion layer 140 may be provided. As described above, in the process of manufacturing the semiconductor device 100, the lower source/drain region 131 and the upper source/drain region 132 may be formed by using the lower insertion layer 120 and the upper insertion layer 140. In particular, the difficulty of the process of forming the lower source/drain region 131 disposed between the channel layer 130 and the bit line 110 in the vertical transistor VCT (refer to FIG. 2) may be reduced. In other words, embodiments of the inventive concept may provide the semiconductor device 100 with reduced process difficulty.

According to embodiments, the semiconductor device 100 including the lower insertion layer 120 and/or the upper insertion layer 140 may be provided. In particular, the lower insertion layer 120 may include the second metal oxide M2_Ox containing a conductive oxide, thereby enhancing the phenomenon of increased resistance of the vertical transistor VCT. Likewise, the upper insertion layer 140 may include the third metal oxide M3_Ox containing a conductive oxide, thereby enhancing the phenomenon of increased resistance of the vertical transistor VCT. Therefore, the on-current of the vertical transistor VCT may be enhanced. In other words, according to embodiments, the semiconductor device 100 including the vertical transistor VCT with enhanced on-current may be provided.

According to embodiments, the semiconductor device 100 including the lower insertion layer 120 and/or the upper insertion layer 140 may be provided. In particular, the lower insertion layer 120 may include the second metal oxide M2_Ox with high mobility, thereby enhancing the on-current of the vertical transistor VCT. Likewise, the upper insertion layer 140 may include the third metal oxide M3_Ox with high mobility, thereby enhancing the on-current of the vertical transistor VCT. In other words, according to embodiments, the semiconductor device 100 including the vertical transistor VCT with enhanced on-current may be provided. Thus, the semiconductor device 100 with improved performance and reliability may be provided.

A method of manufacturing the semiconductor device 100 shown in FIGS. 1, 2A, 3A, and 3B has been described above as an example with reference to FIGS. 8 to 13. However, it would be obvious to one of ordinary skill in the art that the semiconductor devices 100A, 100B, and 100C shown in FIGS. 4A to 4C, the semiconductor devices 200, 200A, and 201 shown in FIGS. 5 to 7, and various semiconductor devices having similar structures thereto may be manufactured by making various modifications to the descriptions given with reference to FIGS. 8 to 13 within the technical spirit of the inventive concept.

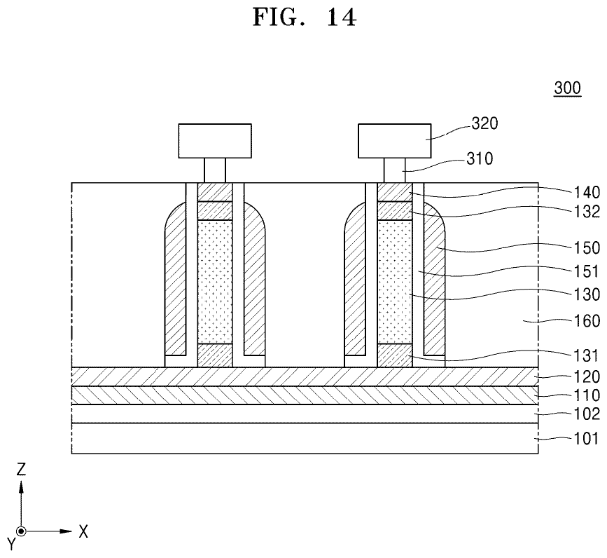

FIG. 14 is a cross-sectional view of a semiconductor device 300 according to embodiments. Referring to FIG. 14, the semiconductor device 300 may include contacts 310 arranged on the upper insertion layer 140 and a memory cell device 320 electrically connected to the lower source/drain region 131, the channel layer 130, and the upper source/drain region 132 through the contacts 310.

For example, the memory cell device 320 may include a capacitor structure. In other words, the semiconductor device 300 may include a dynamic random access memory (DRAM) device. For example, the semiconductor device 300 may include a ferroelectric RAM (FeRAM) or a selector only memory (SOM).

While the disclosure has been particularly shown and described with reference to embodiments thereof, it will be understood that various changes in form and details may be made therein without departing from the spirit and scope of the following claims.

What is claimed is:

1. A vertical channel transistor, comprising:
a substrate having a bit line thereon;
a channel layer comprising a first metal oxide, on the bit line;
a lower insertion layer extending between the bit line and a first end of the channel layer, and comprising a second metal oxide having a greater bonding energy relative to the first metal oxide;
a lower source/drain region extending between the first end of the channel layer and the lower insertion layer, and comprising a first metal dopant that is a reduced form of the first metal oxide;
an upper source/drain region electrically connected to a second end of the channel layer, and comprising the first metal dopant; and
an insulated gate line on the channel layer.

2. The transistor of claim 1,
wherein the channel layer extends lengthwise is a vertical direction relative to a surface of the substrate;
wherein the first metal oxide comprises at least one InₓGa_{y}Zn_{z}O material, where: 0≤x<1, 0≤y<1, and 0≤z<1; and
wherein the second metal oxide is selected from among aluminum oxide, tungsten oxide, titanium oxide, tantalum oxide, molybdenum oxide, ruthenium oxide, cobalt oxide, germanium oxide, indium tin oxide, and tin oxide.

3. The transistor of claim 1, wherein the lower insertion layer comprises a first region overlapping the lower source/drain region in the vertical direction; and wherein the first region comprises the second metal oxide.

4. The transistor of claim 3, wherein the lower insertion layer further comprises a second region that does not overlap the lower source/drain region in the vertical direction; and wherein the second region comprises a second metal dopant that is a reduced form of the second metal oxide.

5. The transistor of claim 1, wherein the lower source/drain region includes oxygen vacancies therein.

6. The transistor of claim 1, wherein the lower insertion layer contacts the lower source/drain region.

7. The transistor of claim 1, further comprising an upper insertion layer, which extends on the upper source/drain region and comprises a third metal oxide that has a greater bonding energy relative to the first metal oxide.

8. The transistor of claim 7, wherein the upper source/drain region includes oxygen vacancies therein.

9. The transistor of claim 7, wherein the upper insertion layer is disposed in contact with the upper source/drain region.

10. The transistor of claim 1, wherein the insulated gate line comprises a gate insulation layer having an L-shaped cross-section; and wherein a vertical portion of the gate insulation layer contacts the channel layer, and a horizontal portion of the gate insulation layer contacts the lower insertion layer.

11. A semiconductor device, comprising:
a substrate;
a bit line extending in a first horizontal direction on the substrate;
a pair of gate lines extending on the bit line in a second horizontal direction intersecting with the first horizontal direction and spaced apart from each other in the first horizontal direction;
a channel layer extending between the pair of gate lines and in a vertical direction, and comprising a first metal oxide;
a gate insulation layer extending between each of the pair of gate lines and the channel layer, and extending in the vertical direction;
an upper insertion layer extending on the channel layer, and comprising a second metal oxide having a greater bonding energy relative to the first metal oxide; and
an upper source/drain region extending between the channel layer and the upper insertion layer and comprising a first metal dopant that is a reduced form of the first metal oxide.

12. The device of claim 11,
wherein the first metal oxide comprises at least one InₓGa_{y}Zn_{z}O material, where: 0≤x<1, 0≤y<1, and 0≤z<1; and
wherein the second metal oxide is selected from among aluminum oxide, tungsten oxide, titanium oxide, tantalum oxide, molybdenum oxide, ruthenium oxide, cobalt oxide, germanium oxide, indium tin oxide, and tin oxide.

13. The device of claim 11, wherein the upper source/drain region has oxygen vacancies therein.

14. The device of claim 11, wherein the upper insertion layer contacts the upper source/drain region.

15. The device of claim 11, further comprising a lower source/drain region spaced apart from the upper source/drain region with the channel layer extending therebetween, said lower source/drain region comprising the first metal dopant.

16. The device of claim 15, further comprising a lower insertion layer extending between the lower source/drain region and the bit line, said lower insertion layer comprising a third metal oxide having a greater bonding energy relative to the first metal oxide.

17. The device of claim 16, wherein the lower insertion layer contacts the lower source/drain region.

18. A semiconductor device, comprising:
a memory cell device; and
a vertical transistor electrically connected to the memory cell device, said vertical transistor comprising:
a substrate;
a bit line extending in a first horizontal direction on the substrate;
a pair of gate lines extending on the bit line in a second horizontal direction intersecting with the first horizontal direction and spaced apart from each other in the first horizontal direction;
a channel layer disposed between the pair of gate lines, extending in a vertical direction, and comprising a first metal oxide;
a gate insulation layer disposed between each of the pair of gate lines and the channel layer and extending in the vertical direction;
a lower insertion layer disposed between the bit line and the channel layer, extending in the first horizontal direction, and comprising a second metal oxide;
a lower source/drain region disposed between the channel layer and the lower insertion layer, contacting the lower insertion layer, and comprising a first metal dopant that is a reduced form of the first metal oxide;
an upper source/drain region spaced apart from the lower source/drain region with the channel layer therebetween and comprising the first metal dopant; and
an upper insertion layer disposed on the upper source/drain region, contacting the upper source/drain region, and comprising a third metal oxide;
wherein the second metal oxide has greater bonding energy than the first metal oxide; and
wherein the third metal oxide has greater bonding energy than the first metal oxide.

19. The device of claim 18, wherein both the lower source/drain region and the upper source/drain region have oxygen vacancies therein.

20. The device of claim 18,
wherein the first metal oxide comprises one or more selected from InₓGa_{y}Zn_{z}O, where x, y, z are equal to or greater than 0 and less than 1; and
wherein the second metal oxide and the third metal oxide are each selected from among aluminum oxide, tungsten oxide, titanium oxide, tantalum oxide, molybdenum oxide, ruthenium oxide, cobalt oxide, germanium oxide, indium tin oxide, and tin oxide.
